(19) United States
(12) Patent Application Publication
(10) Pub. No.: US 2004/0048437 A1
(43) Pub. Date: Mar. 11, 2004

(54) Method of making oxide embedded transistor structures

(76) Inventor: Valery M. Dubin, Portland, OR (US)

Correspondence Address: BLAKELY SOKOLOFF TAYLOR & ZAFMAN, 12400 WILSHIRE BOULEVARD, SEVENTH FLOOR, LOS ANGELES, CA, 90025, US

(21) Appl. No.: 10/241,123

(22) Filed: Sep. 11, 2002

(51) Int. Cl. H01L 21/336; H01L 21/76

(52) U.S. Cl. 438/296; 438/424

(57) ABSTRACT

A method including forming at least two monocrystalline layers of different resistance values in a surface of a substrate, protecting an area of the surface of the substrate, forming a trench in a non-protect area of the surface of the substrate to a body of the substrate, anodically etching a portion of the substrate body; and oxidizing the anodically etched portion of the substrate body. An apparatus including a device substrate having an active area including an epitaxial layer over an oxidized portion of the body of the substrate, wherein the active area is defined by a trench formed in the substrate to a point beyond the epitaxial layer; and at least one device formed in or on the active area of the device substrate.

### BACKGROUND

1. Field

Circuit structures and methods of forming circuit substrates.

2. Relevant Art

Circuit structures (e.g., transistors, capacitors, resistors, diodes, etc.) are typically formed in and/or on a circuit substrate such as a semiconductor material. Traditionally, circuit substrates are a semiconductor material such as silicon. In terms of formation of devices thereon and/or therein, a bulk semiconductor substrate is often modified to include regions of different conductivity. For example, transistor devices generally are formed on and in a bulk semiconductor substrate over a well of a particular conductivity type (e.g., P-type or N-type). Individual devices (e.g., transistors, capacitors, etc.) are typically isolated from one another on bulk semiconductor substrate by the formation of isolation regions of dielectric materials formed in the substrate about the active or passive device elements that need to be isolated. Some of these methods include trench isolation and oxidation of porous silicon layers.

Another type of circuit substrate is a monocrystalline semiconductor layer on an insulator. One widely known technology is silicon on insulator (SOI). Such substrates offer advantages over a bulk semiconductor substrate in terms of dielectric isolation, omission of a well, and minimizing latch up.

SOI structures may be fabricated by various methods. One method called separation by ion-implanted oxygen or SIMOX involves implanting oxygen by ion implantation into a monocrystalline silicon substrate to create an oxide layer. The implantation time is typically relatively long and the wafer cost is high. Further, many crystal defects typically remain.

Another method of forming an SOI structure involves forming an oxide layer on a first monocrystalline silicon substrate and a defect layer in a second monocrystalline substrate and bonding the first and second substrates. The bonded structure is then annealed and broken at the defect layer to leave a monocrystalline layer of silicon over the oxide layer. Problems with this method involve the cost in processing two wafers as well as the control of the defect layer which ultimately defines the monocrystalline layer of the substrate.

SOI structures can also be formed by techniques based on porous silicon. One technique forms oxidized porous silicon underneath and on the sides of monocrystalline silicon “islands” by selective anodization of P/P+/P or N/N+/N structures to form porous silicon followed by oxidation. One disadvantage of this method is porous silicon propagation into N-type (or P-type) silicon islands. This propagation makes it difficult to control the dimensions of the silicon islands. Further, the oxidation of porous silicon underneath the silicon islands may not be complete due to blocking of oxidation by oxidized N-type or P-type silicon above. The incomplete oxidation tends to decrease breakdown field and increases the dielectric constant of the oxidized porous silicon (which leads to an increase in parasitic capacitance).

A second method of forming SOI structures based on porous silicon involves oxidation of porous silicon underneath an epitaxial silicon layer previously formed on porous silicon. One disadvantage of this technique is that defects may be formed in the epitaxial silicon since it grows on a porous silicon surface.

A third technique of forming an SOI structure based on porous silicon is bonding a first silicon substrate with a porous silicon layer and an epitaxial layer formed on the surface of the porous silicon layer to a thermally oxidized silicon substrate. A water-jet may be used to split the bonded wafers at the porous silicon layer and any remaining exposed porous silicon is etched to reach an epitaxial layer with a hydrogen anneal to treat the surface. One disadvantage of this method is that defects can be formed in the epitaxial silicon since it grows on a porous silicon surface. Further, the use of bonding and water-jets to separate wafers are not manufacturing processes suitable for high volume manufacturing.

### BRIEF DESCRIPTION OF THE DRAWINGS

FIG. 1 shows a cross-sectional side view of a portion of a semiconductor substrate having a first epitaxial layer formed on a surface thereof.

FIG. 2 shows the structure of FIG. 1 following the formation of a second epitaxial layer on the surface of the substrate of a different resistance value than the first epitaxial layer.

FIG. 3 shows the structure of FIG. 2 following the formation of a masking layer on the surface of the substrate.

FIG. 4 shows the structure of FIG. 2 following the formation of trenches in unmasked areas of the surface of the substrate to the first epitaxial layer.

FIG. 5 shows a planar top view of the structure of FIG. 4.

FIG. 6 shows the structure of FIG. 4 following the formation of spacers along the sidewalls of the trenches.

FIG. 7 shows the structure of FIG. 6 following the formation of a porous layer from the first epitaxial layer.

FIG. 8 shows the structure of FIG. 7 following oxidation of the porous layer.

FIG. 9 shows the structure of FIG. 8 following the introduction of a dielectric material over the surface of the substrate.

FIGS. 10 shows the structure of FIG. 9 after exposing the second epitaxial layer on a surface of the substrate.

FIG. 11 shows the structure of FIG. 10 following the formation of a device within a region of the portion of the substrate.

The features of the described embodiments are specifically set forth in the appended claims. The embodiments are best understood by referring to the following description and accompanying drawings, in which similar parts are identified by like reference numerals.

### DETAILED DESCRIPTION

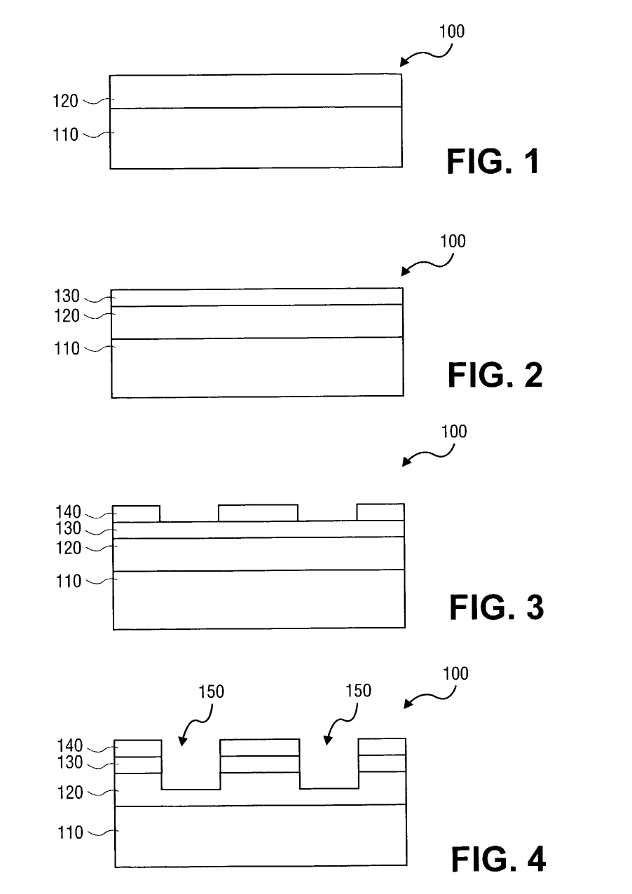

FIG. 1 shows a portion of a circuit substrate that, in one embodiment, is a semiconductor substrate. Reference will be made herein, for purposes of description, to a silicon semiconductor material. Structure 100 includes silicon body 110 which may have a P-type (e.g., a dopant concentration on the order of 10¹⁶ to 10¹⁸ atoms/cm³) or N-type conductivity (e.g., a dopant concentration on the order of 10¹⁶ to 10¹⁸ atoms/cm³) and corresponding resistance value.

Overlying silicon body 110 in structure 100 of FIG. 1 (as viewed) is epitaxial layer 120. First epitaxial layer 120 is, for example, either N⁺-type or -P⁺-type. First epitaxial layer 120 may be formed by, for example, implanting arsenic (N-type) or boron (P-type) to a thickness on the order of, for example, 0.1 to 10 microns (μm) thickness.

FIG. 2 shows the structure of FIG. 1 following the formation of second epitaxial layer 130. In one embodiment second epitaxial layer has a conductivity type and resistance value of N-type or P-type. Second epitaxial layer 130 may be formed, for example, by ion implantation to a thickness on the order of 0.005 to 10 pm.

FIG. 3 shows the structure of FIG. 2 following the formation of masking layer 140 on second epitaxial layer 130. In one embodiment, masking layer 140 is selected of a material that will be resistant to constituents used in a subsequent electrolytic or anodic etching process of an epitaxial layer of the substrate. Masking layer 140 is also selected, in one embodiment, to be a material that is resistant to a chemical or physical etch process to form trenches in the monocrystalline silicon of first layer 120 and second layer 130 (e.g., a material that is selectively less etchable than silicon in the presence of a silicon etchant). Suitable materials include, but are not limited to, silicon nitride, a combination of silicon nitride and polycrystalline silicon (polysilicon), silicon carbide and a combination of silicon carbide and polysilicon. In one embodiment, masking layer 140 is deposited and patterned to define islands that may serve, representatively, as areas of structure 100 where active and/or passive devices are formed. A representative island area according to current technologies is on the order of one micron by one micron.

Referring to FIG. 4, once masking layer 140 is formed and patterned, trenches are formed in the area openings of masking layer 140. In one embodiment where structure 100 includes first epitaxial layer 120 and second epitaxial layer 130, a suitable trench formation process forms trenches to a depth of second epitaxial layer 130. In another embodiment, a suitable trench depth proceed into first epitaxial layer 120. In still another embodiment, the trench depth may proceed beyond the epitaxial layers into body 110. FIG. 4 shows trenches 150 formed to a depth into first epitaxial layer 120.

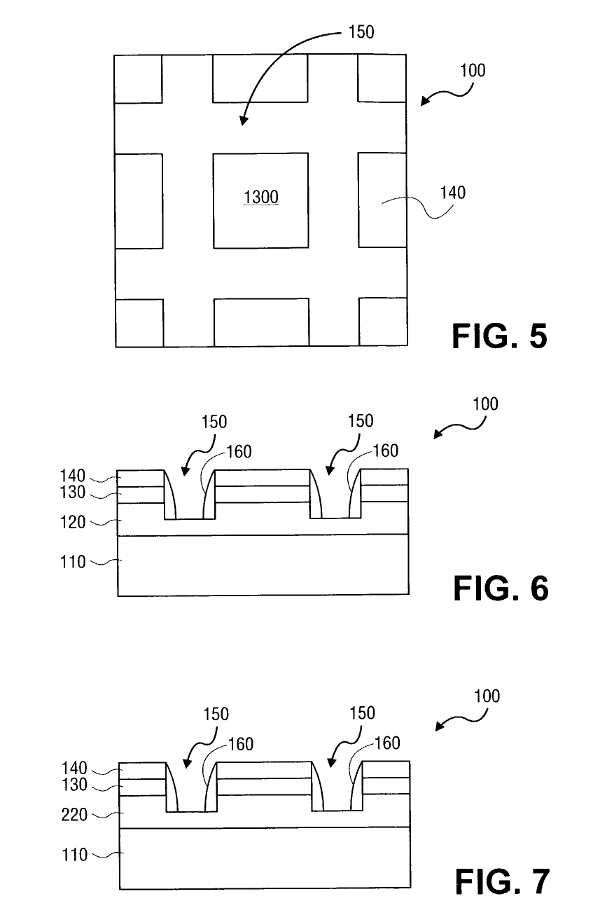

Trenches 150 of FIG. 4 define areas of structure 100 (e.g., areas of surface 100) where active or passive devices may be formed. Referring to FIG. 5, a planar top view of the portion of structure 100 is shown. From this view, area 1300 is, for example, an area defining an island upon or in which active or passive device(s) may subsequently be formed.

FIG. 6 shows the structure of FIG. 4 after the formation of spacer material 160 on the sidewalls of trenches 150. Spacer material 160 may be selected of a material similar to the material selected for masking layer 140, such as silicon nitride, silicon carbide, or a combination of silicon nitride or silicon carbide and polysilicon. The spacer material may be formed, for example, by a deposition process into trenches 150 followed by an anisotropic etch to remove spacer material from the base of the trench. In this manner, in FIG. 6, the base of the trench is exposed first epitaxial layer 120. The formation of spacer material 160 along the sidewalls of trenches 150 is optional in the described process.

FIG. 7 shows the structure of FIG. 6 following the etching of first epitaxial layer 120 to form porous silicon layer 220. One way a porous silicon layer may be formed is by anodizing structure 100 in an aqueous hydrofluoric (HF) acid solution at a current density sufficient to achieve porosity (e.g., 2 to 100 milliamps/cm². A suitable anodizing solution includes HF in a range of about 10 to 50 percent. The specific concentration of HF in any particular solution may depend on factors such as device configuration, dopant concentration, solution temperature, current density, illumination, etc. Substrate body 110 is made the anode while a suitable plate in a solution acts as a cathode. One selected porosity for the silicon of first epitaxial layer 120 may be in the range of 50 to 80 percent.

Referring to FIG. 7, an anodization process proceeds, in this example, in epitaxial layer 120 through trenches 150. By using anodic potentials in the range of 1 volt to 15 volts, selective porous silicon formation may be formed in the N⁺-type or P⁺-type first epitaxial layer to the exclusion of body 110 or second epitaxial layer 130.

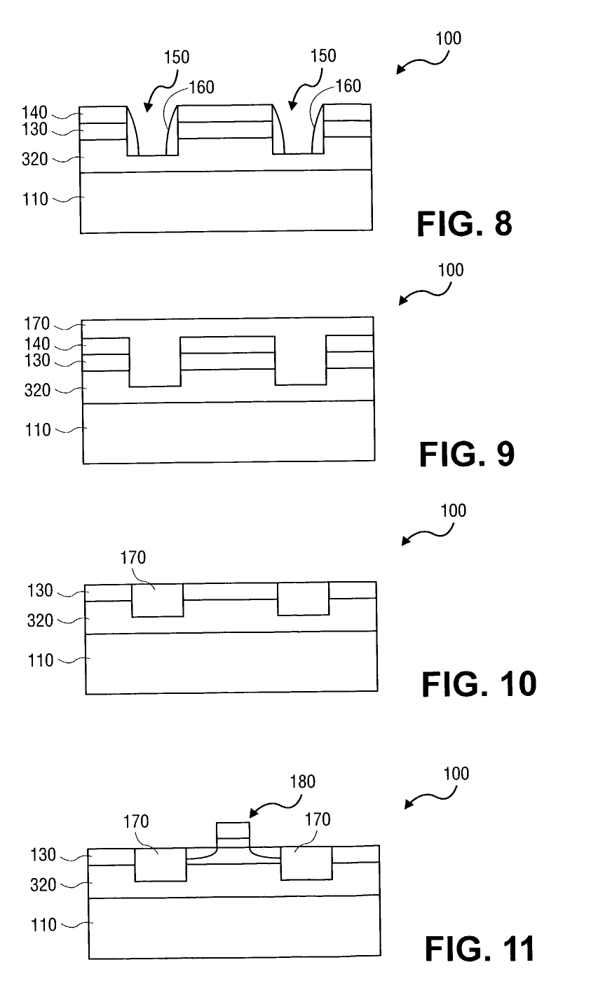

FIG. 8 shows the structure of FIG. 7 following the oxidation of porous layer 220 to silicon dioxide layer 320. One technique for oxidizing porous layer 220 is subjecting structure 100 to an oxidizing ambient of about 700° C. to about 1000° C. Since porous regions tend to oxidize much faster than the remaining silicon body, oxidize layer 320 will form rapidly, much faster than the formation of an oxide in second epitaxial layer 130. Still further, in the case of a structure including optional spacer material 160, the oxidation of porous layer 220 may be performed without blocking oxygen diffusion by superior (as viewed) porous silicon material since trenches 150 are formed instead of superior porous silicon materials. In other words, trenches 150 may provide for lateral oxidation of porous silicon.

FIG. 9 shows the structure of FIG. 8 following the introduction of dielectric material 170 into trenches 150. Dielectric material 170 may be introduced as a blanket over structure 100 to fill trenches 150 and overlie (as viewed) the structure. FIG. 10 shows the structure of FIG. 9 following an etch or planarization to expose second epitaxial layer 130 on a surface of structure 100. In one embodiment, a chemical mechanical polish (CMP) may be used to remove dielectric material 170 (e.g., SiO₂) and a chemical mechanical polish or etch may then be used to remove masking layer 140. An optional polish or etch may be used to thin second epitaxial layer 130 if desired.

FIG. 11 shows the structure of FIG. 10 following the formation of device 180 in area 1300 of structure 100. Device 180 is, for example, an active or passive device such as a transistor, capacitor, diode, etc. Device 180 is isolated from adjacent devices by trench 170 and from the body of the substrate by oxidation layer 320.

The above process describes the formation of an SOI structure and isolated devices thereon. In addition to the use in device isolation, the techniques described may be used to form waveguides in optoelectronics. Based on the description above, anodization may be achieved in areas of semiconductor material (e.g., silicon) having high conductivities relative to other areas or regions of a particular substrate. By selectively implanting areas of high conductivity on a substrate, such areas may be anodized and oxidized. In this manner, waveguides of, for example, silicon dioxide may be formed in desirable areas or regions of substrates. The trenching techniques may be used to promote the anodization and oxidation of such waveguides over techniques described and/or practiced previously.

In the preceding detailed description, specific embodiments were described. It will, however, be evident that various modifications and changes may be made thereto without departing from the broader spirit and scope as set forth in the claims. The specification and drawings are, accordingly, to be regarded in an illustrative rather than a restrictive sense.

What is claimed is:

1. A method comprising:
forming at least two monocrystalline layers of different resistance values in a surface of a substrate;
protecting an area of the surface of the substrate;
forming a trench in a non-protected area of the surface of the substrate to a body of the substrate;
anodically etching a portion of the body of the substrate; and
oxidizing the anodically etched portion of the body of the substrate.

2. The method of claim 1, wherein one of the at least two layers is formed in the body of the substrate and anodically etching and oxidizing comprises anodically etching and oxidizing the one of the at least two layers.

3. The method of claim 1, wherein forming the at least two monocrystalline layers of different resistance values comprises introducing a species into the surface of the substrate at a first concentration for a first layer and a second different concentration for a second layer.

4. The method of claim 3, wherein the at least two monocrystalline layers are of the same conductivity type and a portion for the body separate from the at least two monocrystalline layers comprises the same conductivity type.

5. The method of claim 1, wherein the trench includes sidewalls and a base and after forming the trench, further comprising:
forming a spacer material along the sidewalls of the trench, wherein the spacer material is resistant to the anodical etching.

6. The method of claim 1, wherein after oxidizing, further comprising forming at least one device in the protected area of the surface of the substrate.

7. A method comprising:
forming a first epitaxial layer having a first resistance value in a surface of a substrate;
forming a second epitaxial layer having a second resistance value in the surface of the substrate, wherein the second resistance value is different than the first resistance value;
forming a trench to a body of the substrate around an active area of the substrate; and
oxidizing the body of the substrate.

8. The method of claim 7, wherein one of the at least two layers is formed in the body of the substrate and oxidizing comprises oxidizing the one of the at least two layers.

9. The method of claim 8, wherein prior to oxidizing, further comprising anodically etching the body of the substrate.

10. The method of claim 1, wherein forming the first epitaxial layer and the second epitaxial layer of different resistance values comprises introducing a species into the surface of the substrate at a first concentration for the first layer and a second different concentration for the second layer.

11. The method of claim 10, wherein the first epitaxial layer and the second epitaxial layer are of the same conductivity type and a portion of the body separate from the two epitaxial layers comprises the same conductivity type.

12. The method of claim 7, wherein the trench includes sidewalls and a base and after forming the trench, further comprising:
forming a spacer material along the sidewalls of the trench.

13. The method of claim 7, wherein after oxidizing, further comprising forming at least one device in the active area of the surface of the substrate.

14. An apparatus comprising:
a device substrate having an active area comprising an epitaxial layer over an oxidized portion of the body of the substrate, wherein the active area is defined by a trench formed in the substrate to a point beyond the epitaxial layer; and
at least one device formed in or on the active area of the device substrate.

15. The apparatus of claim 14, wherein the oxidized portion of the body of the substrate comprises a first portion of the body, the body of the substrate further comprising a second portion of a conductivity type and the oxidized portion of the body comprises an interface between the epitaxial layer and the second portion of the body.

16. The apparatus of claim 14, wherein the conductivity type of the epitaxial layer and the second portion of the body is similar.
